(19) United States
(12) Patent Application Publication
(10) Pub. No.: US 2025/0169144 A1
(43) Pub. Date: May 22, 2025

(54) SEMICONDUCTOR ELEMENT WITH OPTIMIZED SHORT-CIRCUIT CAPABILITY

(71) Applicant: Robert Bosch GmbH, Stuttgart (DE)

(72) Inventors: Alberto Martinez-Limia, Pliezhausen (DE); Dragos Costachescu, Reutlingen (DE); Jan-Hendrik Alsmeier, Pfullingen (DE); Wolfgang Feiler, Reutlingen (DE); Holger Bartolf, Ofterdingen (DE); Stephan Schwaiger, Bodelshausen (DE)

(21) Appl. No.: 18/947,007

(22) Filed: Nov. 14, 2024

(30) Foreign Application Priority Data
Nov. 17, 2023 (DE) 10 2023 211 484.4

(51) Int. Cl. H10D 64/23; H10D 30/66; H10D 62/832; H10D 62/85; H10D 84/01; H10D 84/83

(52) U.S. Cl. CPC H10D 64/252; H10D 30/668; H10D 84/839; H10D 62/8325; H10D 62/8503; H10D 84/0149

(57) ABSTRACT

A transistor component, in particular a trench power MISFET. The transistor component includes a substrate preferably made of silicon carbide, silicon, or gallium nitride, a source contact, a drain contact, and a trench structure with a gate.

### FIELD

The present invention relates to a transistor component, in particular a trench power MISFET having a source contacting with a variable contact area for optimizing the short-circuit capability. In particular, the trench power MISFET includes at least two unit cells which have source contacting designs that are different from one another. The present invention furthermore relates to a method for producing a corresponding transistor component.

### BACKGROUND INFORMATION

Power transistors such as power MISFETs (metal insulator semiconductor field effect transistors) represent a special type of MISFET that is designed to process high power in electronic circuits. In particular, trench power MISFETs, for example based on silicon carbide (SiC), represent one of the preferred solutions for electronic power switches used in high-voltage applications in electromobility, such as inverters, chargers, etc. The trench structure makes it possible to further reduce the on-resistance (RDS(on)) and to improve the performance capability of the transistor. One of the requirements for such power MISFETs is to achieve a low forward resistance in order to minimize static power losses while ensuring a low saturation current, which is required to reduce the energy consumed during short-circuit events.

A disadvantage of the trench power MISFETs from the related art (cf. FIG. 1) is that the saturation current cannot be reduced too much without leading to significant losses in the on-state resistivity (RonA) or to impairment of other important MOSFET parameters. The saturation current is generally limited by the forming conductive channel and the JFET effect, which results from adjacent lateral space charge zones in the semiconductor structure, which are formed at the junction between lateral regions of the component.

One way to reduce the saturation current would be to increase the channel resistance, e.g., by increasing the thickness of the insulator of the trench structure or by increasing the doping or the thickness of a body region arranged under a source region, or a combination thereof. However, this would have a negative effect on the on-state resistivity (RonA) or lead to impairment of other important MOSFET parameters, such as increasing the threshold voltage beyond the usable range.

Another way to reduce the saturation current would be to increase the JFET effect so that the additional voltage drop in this region limits the increase in the channel voltage and thus reduces the saturation current. This could be achieved by increasing the width of the lateral regions in the component or by reducing the doping of a region arranged between the lateral regions, or by a combination of both. However, this also leads to an undesirably strong increase in the resistance of the region arranged between the lateral regions and thus to an undesirable increase in the resistivity (RonA).

An object of the present invention is to address the disadvantages described above and to provide an improved transistor component.

### SUMMARY

The present invention relates to a transistor component, in particular a trench power MISFET. According to an example embodiment of the present invention, the transistor component includes a substrate preferably made of silicon carbide (SiC), silicon (Si), or gallium nitride (GaN), a source contact, a drain contact, and a trench structure with a gate, wherein the transistor component comprises a parallel circuit of at least two unit cells, and wherein a contact area of the source contact with a subjacent contiguous source region for a second unit cell is designed to be smaller in comparison with a first unit cell.

The design according to the present invention of the transistor component offers the advantage that the series resistance of the regions connected to the source contacting, in particular n+ source regions, is increased by the variable structuring of the source contacting, in particular a local reduction of a metal contact area in one of the adjacent unit cells, wherein the saturation current can be reduced with fewer disadvantages for the total RdsOn. In particular, the effective voltage between gate and source (VGS) is reduced, which leads to a reduction in the saturation current.

In a preferred example embodiment of the present invention, the contact area of the source contact has, in a plan view, a contour that varies above the source region of the two unit cells. In this case, the contact area of the source contact can have, in a plan view, an at least partially rectangular, polygonal, and/or circular contour. In deviation from the related art, in which each contact area is usually designed as a contact strip which has a constant width and extends substantially perpendicularly to a plurality of unit cells of a semiconductor component that are arranged in parallel with one another, the source contact thus has a contoured contact area such that a contact area which varies for each contacted unit cell is formed between the source metallization and a subjacent source region.

In a preferred example embodiment of the present invention, the contact area of the source contact has at least one local recess in the form of a contact area reduction, which is formed at least in one of the two unit cells. The contact area reduction may be in the form of a rectangular, polygonal, and/or circular cutout in the otherwise continuously applied metallization of the source contact. The contact area of the source contact may preferably have two recesses arranged directly opposite one another or at least partially offset from one another on both sides of the trench structure, as seen in a plan view of the semiconductor component.

In a preferred example embodiment of the present invention, the source contact is only contacted with the subjacent source region of one of the two unit cells, in particular with a first unit cell. Further preferably, a source region of one of the two unit cells, in particular of the second unit cell, is free of a superjacent contact area of a source contact. In this case, no current flows through the source region of the second unit cell, which is not connected to the source contact of the transistor component, toward the surface and to the source contact.

In a preferred example embodiment of the present invention, in a plan view of the unit cells, a contact area of the source contact with the subjacent source region of the unit cells has an area equal to or smaller than the area of an adjacent recess in the source contact.

Except for the source contacting, which is designed differently from one another, the two unit cells of the transistor component preferably have an otherwise identical structural design.

In a preferred example embodiment of the present invention, each unit cell of the transistor component comprises a highly doped n+ substrate, on which an n-doped drift region and, optionally, a buffer region arranged in between are arranged. The buffer region preferably has a higher n-doping than the drift region.

Preferably, each unit cell of the transistor component comprises a trench structure or a trench which is filled with a thin dielectric layer. This dielectric layer may in particular comprise or be formed on silicon oxide, hafnium oxide, aluminum oxide-silicon nitride or a combination of a plurality of insulating materials with different dielectric constants. The dielectric layer may have different thicknesses at the bottom and at the side walls of the trench structure. The trench structure is advantageously filled with a highly conductive material, preferably n+-doped polysilicon, and forms a gate or a gate electrode which is connected to a metal gate contact.

Preferably, each unit cell of the transistor component comprises laterally arranged, deep p+-doped regions which extend from the upper side of the semiconductor structure laterally and deeper than the trench structure into the drift region. Arranged between the lateral p+-doped regions is preferably an n-doped intermediate region, the n-doping of which is higher than the n-doping in the drift region, whereby the on-state resistivity of the component can be reduced.

Preferably, each unit cell of the transistor component comprises a p-doped body region or layer arranged between the trench structure and the lateral, deep p+-doped regions, and a superjacent source region which is connected to the source contact. The source contact forms a low-resistance contact to the source region and to the lateral, deep p+-doped regions.

In a preferred example embodiment of the present invention, the source region of the first unit cell is formed as an n+-doped region, and a subjacent body region or layer is formed as a p-doped region. Further preferably, the source region of the second unit cell is formed as an n+-doped region, and a subjacent body region or layer is also formed as a p-doped region.

Here, the source contact is preferably formed as a contiguous metallization, which completely or partially contacts the lateral, deep p+-doped regions and the source regions of the two unit cells.

The transistor component according to the present invention may be an n-channel MISFET, as described above, or a p-channel MISFET. In the latter case, the corresponding dopings n, p are swapped and the sign of the voltages changes from positive to negative. This shall be deemed to be equally disclosed for the device according to the present invention.

The transistor component according to the present invention is preferably suitable for a variety of power electronics applications, in particular for inverters for industrial drives, renewable energy generation, automotive applications, train drives, and for use in high-voltage rectifiers.

In a further aspect, the present invention relates to a method for producing a transistor component of the present invention as described above. According to an example embodiment of the present invention, the method comprises a plurality of method steps for forming, in particular depositing, a layer sequence on a substrate. Here, fundamentally conventional semiconductor technology methods and techniques can be used with regard to layer growth, layer structuring, and the possible influencing and processing of formed, in particular grown, layers.

According to an example embodiment of the present invention, the method comprises the step of designing a source contact differently for two adjacent unit cells of the transistor component, such that a contact area of the source contact with a subjacent contiguous source region for a second unit cell is designed to be smaller in comparison with a first unit cell.

The method according to an example embodiment of the present invention preferably comprises a lithography step with a structured mask, wherein a contact metallization serving as a source contact for a first unit cell is designed differently from the adjacent second unit cell.

In order to avoid repetition, with respect to the further features of the method according to the present invention, reference is made to the above-described features of the semiconductor component according to the present invention, which are to be deemed to be equally disclosed for the method according to the present invention, and vice versa.

Further advantages, features, and details of the present invention can be found in the following description of preferred embodiments of the present invention and with reference to the drawings.

### BRIEF DESCRIPTION OF THE DRAWINGS

FIG. 1 shows a section through a unit cell of a trench power MISFET according to the related art.

FIG. 2A shows a plan view of a trench power MISFET according to a first example embodiment of the present invention.

FIG. 2B shows a lateral sectional view of a first unit cell of the semiconductor component according to FIG. 2A along the section plane A.

FIG. 2C shows a lateral sectional view of a second unit cell of the semiconductor component according to FIG. 2A along the section plane A′.

FIG. 3A-3D show a schematic representation of the production steps for obtaining the semiconductor component according to an example embodiment of the present invention.

FIG. 4A-4C show a plan view of a trench power MISFET according to further example embodiments of the present invention.

### DETAILED DESCRIPTION OF EXAMPLE EMBODIMENTS

Identical elements or elements which have the same function are provided with the same reference signs in the figures.

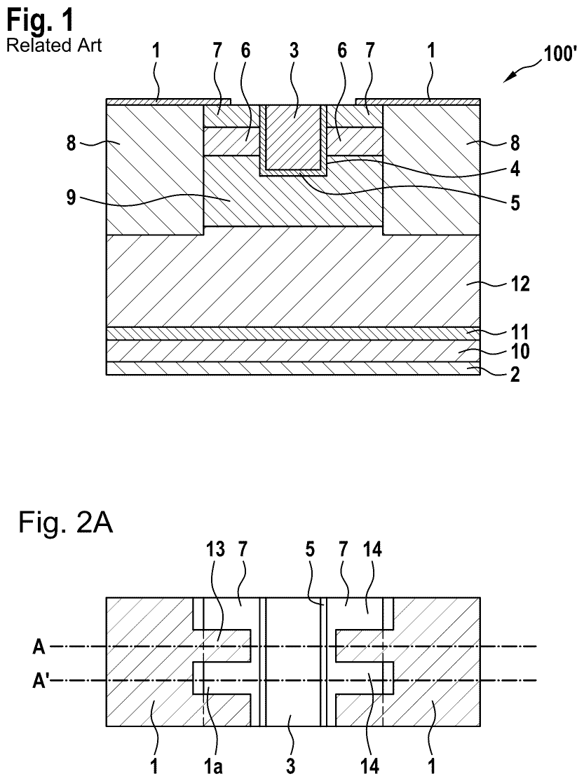

FIG. 1 shows a structure, from the related art, of a semiconductor component which forms a trench power MISFET 100′, wherein only one unit cell is shown for the sake of simplicity. The specific structure of an edge termination is not shown and can be realized in different and conventional ways.

The trench power MISFET 100′ comprises a highly doped n+ substrate 10, on which an n-doped drift region 12 is arranged. Optionally, a buffer region 11 may be arranged between the substrate 10 and the drift region 12. Furthermore, the component comprises a conventional trench structure 4, which has a thin dielectric layer 5 and is filled with a highly conductive material 3, usually n+-doped polysilicon. This highly conductive material forms the gate electrode, which is connected to a metal gate contact (not shown) and is galvanically separated from a source metallization 1 by an insulation layer (not shown).

The trench power MISFET 100′ furthermore comprises laterally arranged, deep p+-doped regions 8, which extend from the upper side of the semiconductor structure deeper than the trench 4 and into the drift region 12. Arranged between the p+-doped regions 8 is preferably an n-doped region 9 of which the n-doping is higher than the n-doping in the drift region 12. The doping in the region 9 may be constant or vary. Alternatively, the region 9 may also extend below the region 8. Furthermore comprised are a p-doped body region 6 and a superjacent n+-doped source region 7, which are arranged on both sides of the trench 4. The source contact or the source metallization 1 forms a low-resistance contact to the source region 7 and to the p+-doped region 8. The body region(s) 6 are indirectly connected to the source contact 1 via the lateral p+-doped regions 8. The substrate 10 is connected to the drain contact 2, which forms a low-resistance contact with the n+ substrate 10.

As soon as a sufficiently high voltage, for example 15-18 V, i.e., a voltage that is higher than the threshold voltage of usually 2-5 V, is applied, an electron inversion layer or an electrically conductive channel forms in the p-doped body region 6 at the interface between the p-doped region and the gate dielectric 5, whereby an electrical conductive path, which consists of the n-doped regions 9, 12, 11, the n+ doped substrate 10, and the drain contact 2, is produced between the n+ source region 7 and the drain. If the drain potential is increased in comparison with the source potential, current starts to flow from the drain contact 2 through the regions 10, 11, 12, 9, the electrical channel, and the source region 7 to the source contact 1.

If a positive voltage is applied between the drain and source contacts 2, 1 while a gate 3 electrode and a source 1 electrode are short-circuited, or, alternatively, if the gate 3 has a negative voltage of a few volts relative to the source in the blocking state, a space charge zone develops at the PN junction between the p-doped region 8 and the n-doped region 9 and at the structure 3, 5, 9. With increasing drain potential, the space charge zone extends downward into the regions 9 and the drift region 12 until it finally reaches the n-doped buffer region 11. The n-doped buffer region 11 is intended to prevent the space charge zone from penetrating into the substrate 10. A peak of the electric field in the blocking mode is located at the bottom of the p+-doped region 8, which shields the trench 4, so that a low electric field strength, typically less than 3 MV/cm for reasons of component reliability, is ensured in the gate dielectric 5. In the case of a short circuit, a high positive voltage occurs between the drain and source terminals while the electrical channel is fully switched on, wherein the gate-source potential is higher than the threshold voltage of usually 2-5 V and typically 15-18 V, as a result of which a very high saturation current flows through the structure. The current is generally limited by the channel but also depends strongly on the distance between adjacent p-doped regions 8, as a result of which, as the voltage between the source and the drain increases, lateral space charge zones form at the junction between the p-doped regions 8 and the n-doped regions 9 due to a JFET effect.

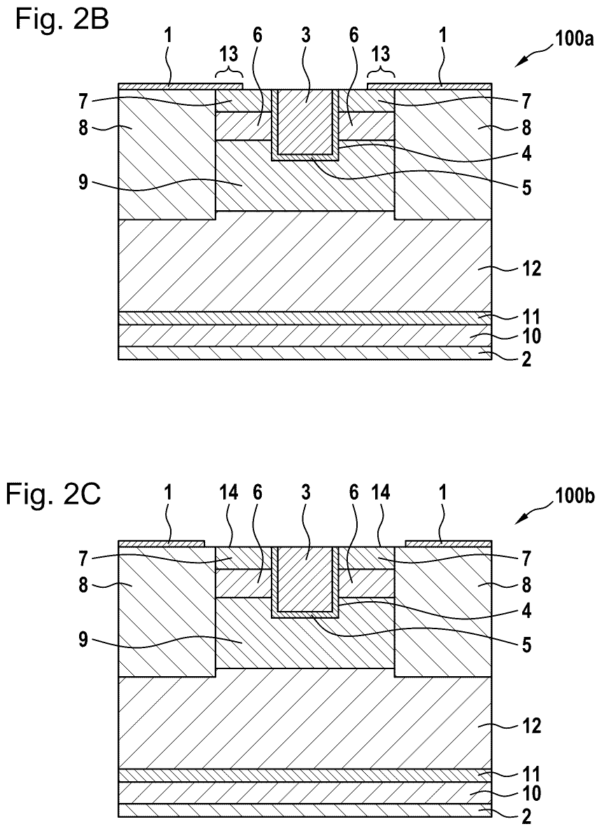

FIG. 2A to 2C show a first preferred exemplary embodiment of a transistor component 100 according to the present invention, comprising at least two unit cells 100a, 100b arranged next to one another (cf. FIG. 2B, 2C). As shown in FIG. 2A, the at least two unit cells 100a, 100b are formed as a parallel circuit. The transistor component may furthermore comprise a plurality of unit cells 100a, 100b, wherein the unit cells 100a, 100b are preferably arranged alternately. The basic structure of the two unit cells 100a, 100b corresponds to the conventional structure as shown in FIG. 1.

According to the present invention, it is now provided that the contact metal 1 of the source is structured such that, in comparison with the related art according to FIG. 1, it does not form a continuous contact strip over the n+ region 7 in a plan view; in particular, it does not form a continuous contact strip over the contiguous source region 7 of the at least two adjacent unit cells. This has the result that the current in the component regions or source regions with a reduced contact area and in particular without a superjacent contact metal 1 flows laterally through the n+ regions 7 toward the contact metal 1 and thereby increases the source series resistance of the component.

The increased voltage drop in the source region leads to a reduction in the effective voltage VGSeff (VGS_{eff}=VGS−Vₜₕ) and thus in the saturation current. The decrease in the saturation current is considerable due to the quadratic dependence of the saturation current on VGS_{eff} (ISC˜VGS_{eff}², cf. B. Jayant Baliga “Silicon Carbide Power Devices,” World Scientific, 2005). The impairment of RonA is significantly lower since the channel portion of Rdson depends only inversely proportionally on VGSeff (Rdson, ch˜1/VGSeff, cf. B. Jayant Baliga “Silicon Carbide Power Devices,” World Scientific, 2005).

As shown in FIG. 2A, the source contact 1 or the source metallization for the at least two adjacent unit cells 100a, 100b is designed differently from one another, such that the contact area 13 of the source contact 1 has a recess 14, in which the source metallization 1 is removed, in at least a second unit cell 100b.

The semiconductor structure of the unit cell in FIG. 2B operates identically to the structure in FIG. 1. In this respect, reference is made to the above description and functionality. However, at gate voltages above the threshold voltage, the current in the structure in FIG. 2C cannot flow vertically directly to the superjacent source metallization, but must travel a longer path to the source contacting of the adjacent unit cell 100a.

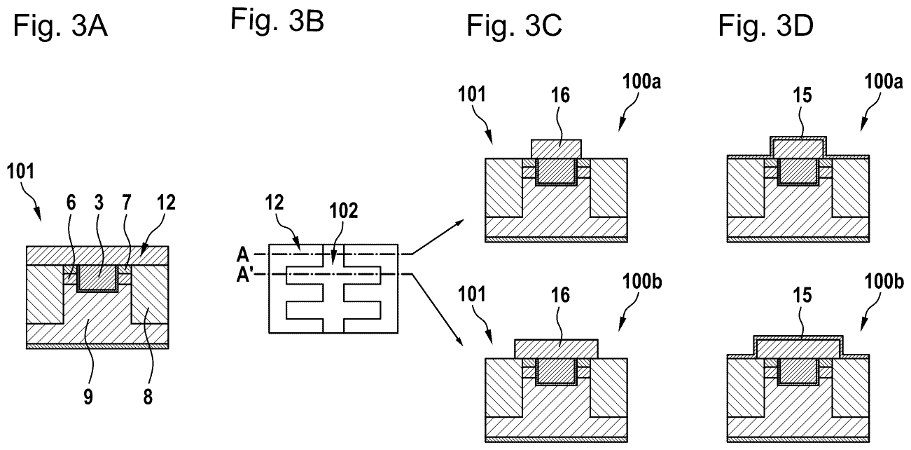

FIG. 3A to 3D schematically show a simplified method sequence for realizing the structures in the unit cells 100a, 100b according to FIG. 2B, 2C, with a focus on the realization of the source contacting 1.

As shown in FIG. 3A, in a first step, the different layers or regions are first formed or deposited on a substrate so that the structural design 101 shown in FIG. 3A is achieved. Here, fundamentally conventional methods and techniques can be used with regard to layer growth, layer structuring, and the possible influencing and processing of formed, in particular grown, layers. The regions 8, 6, 9, 3, 7 in the upper region of the structure 101 are here already formed in accordance with the later component structure. An insulation layer 16 is also formed on the surface of the semiconductor component.

As shown in FIG. 3B and 3C, which show a plan view of the semiconductor component 101 and a sectional view of the two unit cells 100a, 100b, the method then comprises a lithography step using a structured mask 102 for structuring the contact areas, in which step the insulation layer 16 for the unit cells 100a, 100b is removed selectively. Subsequently, a contact metallization layer 15 is applied to form the source contact 1 of the structure, as shown in FIG. 3D, wherein this layer is formed differently for the two unit cells 100a, 100b.

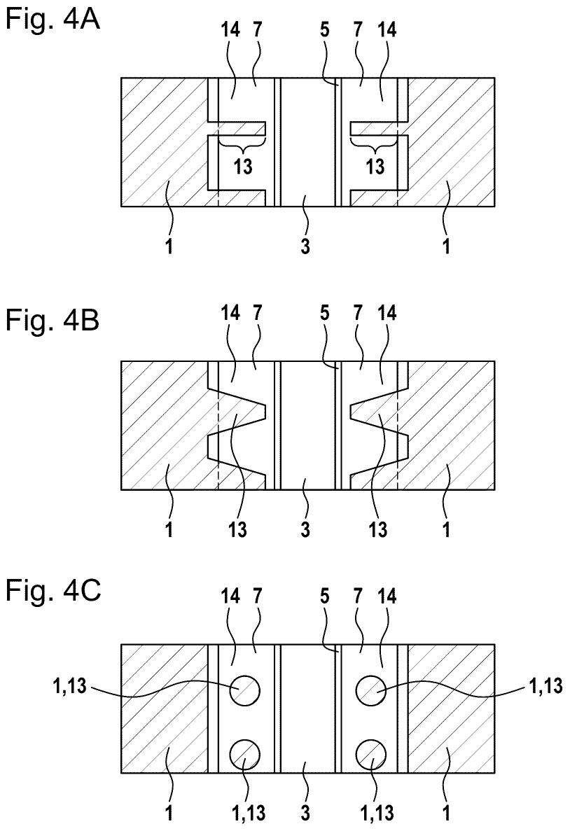

FIG. 4A-4C show further preferred embodiments in a plan view (analogous to FIG. 2A), in which the source contacting 1 is structured differently.

FIG. 4A shows an embodiment in which the contact area 13 of the source contacting 1 with the subjacent contacted n+ source region 7 is significantly smaller than the non-contacted source region 7 in the region of the recesses 14. A lower limit of the contacted n+ area can be specified by electromigration limits or by the maximum permissible increase of Rdson.

FIG. 4B and 4C show further preferred embodiments for the source contacting 1. In this case, the source contacting 1 may have recesses 14 which taper or become larger in the component longitudinal direction L, perpendicularly to a trench extension direction. Furthermore, the source contacting 1 may comprise only pointwise-arranged contact areas 13, which are contacted with the subjacent source region 7. These regions are preferably arranged only in a first of two unit cells 100a, 100b. Patterns deviating from the arrangements shown in FIG. 4A-4C, or combinations thereof are also possible.

As shown in FIG. 2A and 4A=4C, the source contacting 1 on one side of the trench structure 4 may be arranged opposite to the source contacting 1 on the opposite side of the trench structure 4. Furthermore, it is possible that the correspondingly arranged source contactings on both sides of the trench structure 4 are not arranged exactly opposite one another, i.e., are arranged at an offset from one another.

The present invention is not limited to an n-channel MISFET described in the exemplary embodiments, but may also be applied to a p-channel MISFET. In this case, the corresponding dopings n, p are swapped and the sign of the voltages changes from positive to negative. The present invention is also not limited to SiC-based semiconductor components, but can equally be applied to other semiconductor materials, in particular silicon or gallium nitride.

1-10. (canceled)

11. A transistor component including a trench power MISFET, the transistor component comprising:
a substrate made of silicon carbide (SiC), or silicon (Si), or gallium nitride (GaN);
a source contact;
a drain contact;
a trench structure with a gate; and
a parallel circuit of at least two unit cells, wherein a contact area of the source contact with a subjacent contiguous source region for a second unit cell of the at least two unit cells is smaller in comparison with a first unit cell of the at least two unit cells.

12. The transistor component according to claim 11, wherein the contact area of the source contact has, in a plan view, a contour which varies above the source region of the at least two unit cells.

13. The transistor component according to claim 11, wherein the contact area of the source contact has, in a plan view, an at least partially rectangular and/or polygonal and/or circular contour.

14. The transistor component according to claim 11, wherein the contact area of the source contact has at least one local recess in a form of a contact area reduction, which is formed at least in one of the two unit cells.

15. The transistor component according to claim 14, wherein the contact area of the source contact has two recesses arranged directly opposite one another or at least partially offset from one another, on both sides of the trench structure.

16. The transistor component according to claim 11, wherein the source contact is contacted only with the subjacent source region of the first unit cell.

17. The transistor component according to claim 11, wherein a source region of the second unit cell is free of a superjacent contact area of the source contact.

18. The transistor component according to claim 11, wherein, except for a design of the source contact that is different from one another, the two unit cells of the transistor component have an otherwise similar structural design.

19. The transistor component according to claim 11, wherein, in a plan view of the at least two unit cells, a contact area of the source contact with the subjacent source region of the at least two unit cells has an area equal to or smaller than an area of an adjacent recess in the source contact.

20. A method for producing a transistor component, the method comprising the following steps:
a plurality of method steps for depositing a layer sequence on a substrate,
wherein a source contact for two adjacent unit cells of the transistor component is configured differently, such that a contact area of the source contact with a subjacent contiguous source region for a second unit cell of the two unit cells is smaller in comparison with a first unit cell of the two unit cells.
